(19) United States
(12) Patent Application Publication
(10) Pub. No.: US 2004/0041281 A1
(43) Pub. Date: Mar. 4, 2004

(54) Semiconductor integrated circuit and method for designing semiconductor integrated circuit

(76) Inventors: Atsushi Sakai, Gifu-shi (JP); Takashi Yamada, Yamagata-shi (JP)

Correspondence Address: McDERMOTT, WILL & EMERY, 600 13th Street, N.W., Washington, DC, 20005-3096, US

(21) Appl. No.: 10/635,505

(22) Filed: Aug. 7, 2003

(30) Foreign Application Priority Data
Aug. 8, 2002 (JP) 2002-230987
Dec. 4, 2002 (JP) 2002-352452

(51) Int. Cl. H01L 23/48

(52) U.S. Cl. 257/784

(57) ABSTRACT

The present invention provides a method of designing a semiconductor integrated circuit with reduced crosstalk noise within a predetermined design time. In the method, various grid pitches are first set. A plurality of trial routing data are generated in accordance with the grid pitches. Wire congestion and crosstalk noise for each of the trial routing data are analyzed. For each routing data, a time needed for a final connection process of wires and the crosstalk noise are predicted. A final grid pitch is determined based on the result of the prediction.

### CROSS-REFERENCES TO RELATED APPLICATIONS

This application is based upon and claims the benefit of priority from prior Japanese Patent Applications No. 2002-230987 filed on Aug. 8, 2002 and No. 2002-352452 filed on Dec. 4, 2002, the entire contents of which are incorporated herein by reference.

### BACKGROUND OF THE INVENTION

The present invention relates to a semiconductor integrated circuit and a design method therefor, and, more particularly, to a method of designing a semiconductor integrated circuit with reduced crosstalk noise or power consumption within a relatively short time.

With the advancement of microfabrication technologies for semiconductor integrated circuits, the wire widths in a semiconductor integrated circuit and the pitch between adjacent wires have become even smaller. The thicknesses of wiring layers in a semiconductor integrated circuit, on the other hand, have not become smaller so much due to the necessity to prevent an increase in wire resistance and electromigration-oriented disconnection. As the microfabrication technique for semiconductor integrated circuits is advanced, the influence of an intralayer coupling capacitance formed between adjacent wires via an insulator in the same wiring layer, rather than the influence of an interlayer coupling capacitance formed between a wire and the substrate via an insulation layer, becomes greater.

One influence of the intralayer coupling capacitance is that crosstalk noise by which the potential of one wire varies the potential of another wire. When the crosstalk noise is large, the probability of malfunction of a semiconductor integrated circuit occurring increases. For example, the generation of noise of type called a glitch, may invert the logic of an output logical signal of a sequential logic circuit or change the signal propagation speed so that the desired operation speed cannot be provided.

The crosstalk noise is particularly likely to occur in a wire connected to a driver with a small drive performance, that is, a wire having a weak charge retaining capability in those wires which are adjacent within the same layer over a long distance at a relatively narrow pitch. At the time of placing and/or connecting functional cells of a semiconductor integrated circuit, it is essential to extract those portions where crosstalk noise may occur and eliminate the crosstalk noise there.

Conventionally, a process of reducing the crosstalk noise was performed after a general-purpose automatic placement and routing tool was used to place functional cells along grid lines at a predetermined pitch and connect the functional cells. In that process, the designer (1) sets the upper limit of the crosstalk noise, (2) extracts the coupling capacitance and the wire resistance, (3) computes the crosstalk noise for every wire, (4) determines whether a violation has occurred due to the computed noise exceeding the predetermined upper limit, (5) sets the pitch of wires associated with that portion (a wiring layer) which has been determined to have caused a violation to twice the predetermined pitch or greater, after which the steps (2) to (4) are repeated. Accordingly, a semiconductor integrated circuit which meets the required level of crosstalk noise is designed.

In place of the step (5), Japanese Laid-Open Patent Publication No. 10-27194 proposes a step (5a) of enhancing the driver performance of a driver or inserting a repeater in order to increase the potential retaining capability of a wire and Japanese Laid-Open Patent Publication No. 2001-148426 proposes a step (5b) of inserting an inverter to cancel out a delay variation originated from crosstalk noise so that the potential variation of one wire and the potential variation of another wire repeat an in-phase state and a reverse-phase state. Similar prior art is also disclosed in Japanese Laid-Open Patent Publication No. 2002-16141.

The steps (1) to (5) are executed after the automatic placement and routing tool connects functional cells. When the wire position is changed in step (5), the wire positions should also be changed for those portions where the crosstalk noise does not exceed the upper limit. As a result, suppression of the crosstalk noise would take a long time.

The steps (5a) and (5b) are performed by a skilled operator. It is not however easy for even a skilled operator to take adequate measures according to the location of a violation. In this respect, suppression of the crosstalk noise would take a long time.

The intralayer coupling brings about another problem such that the coupling of adjacent wires increases the power consumption of the semiconductor integrated circuit. To reduce the power consumption of the semiconductor integrated circuit, it is desirable to efficiently suppress the intralayer coupling.

### SUMMARY OF THE INVENTION

One aspect of the present invention is a semiconductor integrated circuit including a wiring layer having a region and a plurality of wires provided substantially in parallel to one another in the region of the wiring layer. Each wire has a center axis extending in the longitudinal direction. A pitch of adjacent wires defined by distance between the center axes is an integer multiple of a predetermined minimum pitch and different from an integer multiple of a minimum design-rule dimension for a fabrication process for the semiconductor integrated circuit.

A further aspect of the present invention is a semiconductor integrated circuit including a plurality of functional blocks each having a predetermined function and including functional cells. A plurality of wires are arranged substantially in parallel to one another in each functional block for connecting the plurality of functional cells together. Each wire has a center axis extending in the longitudinal direction. A pitch of the wires defined by distance between the center axes is an integer multiple of a minimum pitch. The minimum pitch in one selected functional block is different from that in another functional block.

A further aspect of the present invention is a semiconductor integrated circuit including a plurality of wiring layers and functional blocks each having a predetermined function and including functional cells. A plurality of wires are arranged substantially in parallel to one another in a predetermined region in at least one layer of the wiring layers for connecting the functional cells together in each functional block. Each wire has a center axis extending in the longitudinal direction. A pitch of the plurality of wires defined by distance between the center axes in each functional block is an integer multiple of a predetermined minimum pitch. The minimum pitch in one selected functional block is different from that in another functional block.

A further aspect of the present invention is a semiconductor integrated circuit including a plurality of wiring layers, with at least one of the wiring layers having first and second regions. A plurality of first wires are arranged in parallel to one another in the first region in the at least one of the plurality of wiring layers. A pitch of the plurality of wires in the first region is an integer multiple of a predetermined first basic pitch. A plurality of second wires are arranged in parallel to one another in the second region in the at least one wiring layer. A pitch of the second wires is an integer multiple of a predetermined second basic pitch. The predetermined first basic pitch is different from an integer multiple of the predetermined second basic pitch.

A further aspect of the present invention is a design method for a semiconductor integrated circuit. The method includes a step of placing a plurality of functional cells and a step of routing a plurality of wires for connecting the functional cells. Each wire has a center axis extending in the longitudinal direction. The step of routing wires includes setting pitches between the center axes of the plurality of wires to either a value of an integer multiple of a minimum design-rule dimension for a fabrication process of the semiconductor integrated circuit or a value equal to or greater than the minimum design-rule dimension and different from an integer multiple of the minimum design-rule dimension.

A further aspect of the present invention is a design method for a semiconductor integrated circuit having a plurality of wiring layers. The method includes setting a wire pitch for each of the plurality of wiring layers, tentatively routing a plurality of wires at the wire pitch set for each layer of the plurality of wiring layers, determining whether all of functional cells of the semiconductor integrated circuit have been connected by that tentative routing, computing a peak value of crosstalk noise produced between the plurality of wires, and checking if the peak value of the crosstalk noise is equal to or less than a predetermined upper limit. The step of tentatively routing, the step of determining and the step of computing are repeated while changing the wire pitch until all connections are completed and the peak value of the crosstalk noise is equal to or less than the predetermined upper limit.

A further aspect of the present invention is a design method for a semiconductor integrated circuit. The method includes placing a plurality of functional cells, setting a plurality of wire pitches, tentatively routing a plurality of wires for connecting the plurality of functional cells in accordance with each of the plurality of wire pitches and tentatively connecting the plurality of functional cells, thereby generating a plurality of trial routing data, analyzing a degree of wire congestion and crosstalk noise for each trial routing of the plurality of trial routing data, predicting connection time needed for a final connection process for the plurality of functional cells for each trial routing of the plurality of trial routing data based on a result of the congestion analysis, predicting crosstalk noise after final connection of the plurality of functional cells for each of the plurality of trial routing data based on a result of the crosstalk noise analysis, and determining an optimal wire pitch from the plurality of wire pitches based on results of predicting the connection time and the crosstalk noise.

A further aspect of the present invention is a design method for a semiconductor integrated circuit including a plurality of functional cells. The method includes the steps of tentatively connecting the plurality of functional cells by a plurality of wires in an arithmetic operation with a relatively small load, thereby generating trial routing data, analyzing a degree of wire congestion and crosstalk noise for the trial routing data, predicting connection time needed for a final connection process for the plurality of functional cells based on a result of the analyzing the degree of wire congestion, predicting crosstalk noise after the final connection process of the plurality of functional cells based on a result of the analyzing crosstalk noise, and evaluating whether the trial routing data is an optimal one or not based on results of predicting the connection time and the crosstalk noise.

A further aspect of the present invention is a design method for a semiconductor integrated circuit having a plurality of wiring layers. The method includes the steps of setting a wire pitch for each layer of the plurality of wiring layers, tentatively routing a plurality of wires at the wire pitch to thereby generate trial routing data, checking a degree of wire congestion of the trial routing data, checking power consumption of the trial routing data, and determining an optimal wire pitch from the degree of wire congestion and the power consumption of the trial routing data.

A further aspect of the present invention is a design method for a semiconductor integrated circuit including a plurality of functional cells. The method includes the steps of setting a wire pitch, tentatively routing a plurality of wires in accordance with the set wire pitch to tentatively connect the plurality of functional cells to generate trial routing data including information for the plurality of wires tentatively routed and the plurality of functional cells, analyzing a degree of wire congestion and power consumption of the trial routing data, and evaluating whether the trial routing data is an optimal one or not, based on the degree of wire congestion and the power consumption of the trial routing data.

A further aspect of the present invention is a design method for a semiconductor integrated circuit having a plurality of wiring layers. The method includes the steps of placing a plurality of functional cells in each of the wiring layers in accordance with a predetermined cell-utilization-ratio, setting a plurality of wire pitches for each of the plurality of wiring layers, generating trial routing data by tentatively routing a plurality of wires for connecting the plurality of functional cells at the set wire pitch, checking a degree of wire congestion of the trial routing data. When the wire congestion is unacceptable, the steps of placing a plurality of functional cells, generating trial routing data and checking the degree of wire congestion are repeated in accordance with a smaller cell-utilization-ratio or in accordance with a smaller wire pitch for at least one wiring layer selected from the plurality of wiring layers. When the wire congestion is acceptable, the crosstalk noise of the trial routing data is checked. The method further includes selecting a trial routing whose wire congestion and crosstalk noise are both optimal, and determining a final layout of the plurality of wires in accordance with that wire pitch that is used for the selected routing.

Other aspects and advantages of the present invention will become apparent from the following description, taken in conjunction with the accompanying drawings, illustrating by way of example the principles of the invention.

### BRIEF DESCRIPTION OF THE DRAWINGS

The features of the present invention that are believed to be novel are set forth with particularity in the appended claims. The invention, together with objects and advantages thereof, may best be understood by reference to the following description of the presently preferred embodiments together with the accompanying drawings in which:

FIG. 1 is a block diagram illustrating a design aiding apparatus for an integrated circuit according to a first embodiment of the present invention;

FIG. 2 is a flowchart illustrating automatic placement and automatic routing procedures according to the first embodiment;

FIG. 3 is a diagram showing the relationship between a grid pitch and a routing completion time;

FIG. 4 is a diagram showing the relationship between the grid pitch and the number of nets at which crosstalk noise has exceeded an upper limit;

FIGS. 5A, 5B and 5C are schematic diagrams of a grid according to the first embodiment;

FIG. 5D is an explanatory diagram of the grid pitch;

FIG. 6 is a table showing a wiring layer designation mode for designating a wiring layer whose wire pitch is to be increased;

FIG. 7 is a diagram exemplarily illustrating the relationship between a cell-utilization-ratio and the routing completion time;

FIG. 8 is an exemplary diagram showing parameters to be used in analyzing crosstalk noise;

FIG. 9 shows data which defines the relationship between the degree of wire congestion after trial routing and the routing completion time and is stored in a database;

FIG. 10 is a diagram showing the distribution of crosstalk noise;

FIG. 11 shows data showing the connection processing times and crosstalk noise for a plurality of trial routing data generated in accordance with the wiring layer designation mode and the grid pitch;

FIG. 12 is a block diagram of a design aiding apparatus for an integrated circuit according to a second embodiment of the present invention;

FIG. 13 is a flowchart illustrating automatic placement and automatic routing according to the second embodiment;

FIG. 14 is a block diagram of a design aiding apparatus for an integrated circuit according to a third embodiment of the present invention;

FIG. 15 is a flowchart illustrating automatic placement and automatic routing according to the third embodiment;

FIG. 16 is a graph showing the relationship between a wire pitch and power reduction ratio; and

FIGS. 17A to 17C, 18, 19A to 19C and 20A to 20E are schematic diagrams of semiconductor integrated circuits according to the present invention.

### DETAILED DESCRIPTION OF THE PREFERRED EMBODIMENTS

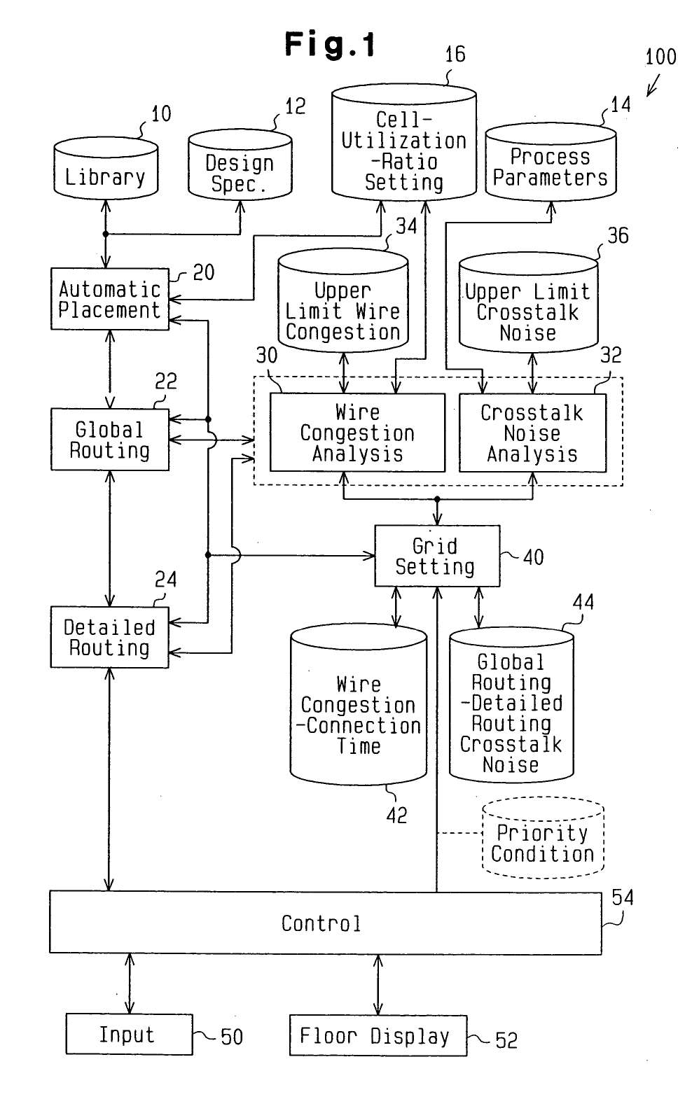

A semiconductor integrated circuit according to the first embodiment of the invention and a design method therefor will be described below. In the first embodiment, a semiconductor integrated circuit is designed in a standard cell design by a design aiding apparatus 100 of FIG. 1.

To begin with, the design aiding apparatus 100 will be discussed.

Stored in a library 10 is performance information for functional cells, such as cell information of various functional cells, delay information of each functional cell and constraint information about the setup/hold time. Each functional cell is formed by a logical operation element (AND (logical product), OR (logical sum), exclusive OR, exclusive AND, NOT), a flip-flop circuit, a memory such as RAM, an analog element such as an A/D converter, or a combination of those elements. The library 10 also stores information for layout of the individual functional cells, signal delay, and power consumption. The library 10 is comprised of a storage device such as a hard disk drive.

A design specification storage section 12 stores information about the functions and structure of a semiconductor integrated circuit which are described in, for example, a hardware description language (HDL). Specifically, the design specification storage section 12 stores information on the types and the quantity of those cells defined in the library 10, which are to be used, and cell connection information. The design specification storage section 12 is comprised of a storage device such as a hard disk drive.

A process parameter storage section 14 stores process parameters, such as the characteristics of elements and wires according to the designated design rule (the minimum design-rule dimension in the fabrication process, the element sizes, and minimum wire pitch) and the characteristics of wires according to their materials. The process parameter storage section 14 is comprised of a storage device such as a hard disk drive. In one embodiment, the library 10 and the storage sections 12 and 14 form layout databases.

A cell-utilization-ratio setting section 16 stores the cell-utilization-ratio or the ratio of the occupying area of functional cells to the total area of the semiconductor integrated circuit to be designed. The cell-utilization-ratio setting section 16 is comprised of a storage device such as a hard disk drive.

An automatic placement section 20, a global routing section 22 and a detailed routing section 24 carry out the layout design for a semiconductor integrated circuit. The automatic placement section 20 performs automatic placement of functional cells. The global routing section 22 and the detailed routing section 24 perform connection processes to connect functional cells which are automatically placed. Layout data stored in the library 10 is used in the automatic placement and the connection process for functional cells. The global routing section 22 and the detailed routing section 24 function as an automatic routing tool.

Specifically, the global routing section 22 performs trial routing process to route a plurality of wires to connect a plurality of functional cells tentatively or temporarily. The detailed routing section 24 performs a final or detail connection process to route a plurality of wires to connect a plurality of functional cells. The calculation load associated with the trial routing process by the global routing section 22 is smaller than the calculation load associated with the detail connection process performed by the detailed routing section 24.

The automatic placement section 20, the global routing section 22 and the detailed routing section 24 include memory devices where programs associated with the connection processes are recorded. The memory devices are, for example, a hard disk drive or a semiconductor memory, such as ROM or RAM.

A net list of a circuit, or trial routing data, generated by the global routing section 22 and the detailed routing section 24 is supplied to a wire congestion analysis section 30 and a crosstalk noise analysis section 32. This net list has a hierarchical structure which includes a net list in a functional block, which is comprised of a plurality of functional cells and a net list between functional blocks.

An upper-limit wire congestion storage section 34 stores the upper limit of the degree of wire congestion. The upper limit of the degree of wire congestion is the upper limit of degree of wire congestion by which the detailed routing section 24 can complete connection of all the cells. The upper limit differs according to, for example, the required connection time or the required space (area). The wire congestion analysis section 30 analyzes the degree of wire congestion based on the upper limit of the degree of wire congestion stored in the upper-limit wire congestion storage section 34 and the net list.

An upper-limit crosstalk noise storage section 36 stores the upper limit of crosstalk noise. The upper limit of crosstalk noises is the upper limit of crosstalk noise for the semiconductor integrated circuit. The upper limit is determined in such a way that the logical inversion of the output logical signal of a sequential logic circuit does not occur and the deviation of the actual operational frequency from the desired operational frequency of the semiconductor integrated circuit caused by a change in signal propagation speed is in an allowable range. The crosstalk noise analysis section 32 analyzes the crosstalk noise based on the upper limit of the crosstalk noise stored in the upper-limit crosstalk noise storage section 36, the net list, and process parameters stored in the process parameter storage section 14.

The wire congestion analysis section 30 and the crosstalk noise analysis section 32 include memory devices which store analysis programs. The memory devices are, for example, a hard disk drive or a semiconductor memory, such as ROM or RAM. Each of the upper-limit wire congestion storage section 34 and the upper-limit crosstalk noise storage section 36 is also comprised of a storage device such as a hard disk drive.

A grid setting section 40 sets cell grids which are used to align functional cells by the automatic placement section 20, routing grids which are used to align wires by the global routing section 22 and the detailed routing section 24. Referring to databases 42 and 44, the grid setting section 40 determines the pitch of the final routing grid lines to be adapted to the semiconductor integrated circuit. Stored in the database 42 is data indicating the correlation between the degree of wire congestion of trial routing data that is tentatively routed by the global routing section 22 and is analyzed by the wire congestion analysis section 30 and time (routing completion time) needed for the connection by the detailed routing section 24. Stored in the database 44 is data indicating the correlation between the result of analysis on the crosstalk noise of trial routing data and the crosstalk noise of a semiconductor integrated circuit which has finally connected functional cells. The grid setting section 40 includes a memory device where a program associated with the setting processes is recorded. The memory device is, for example, a hard disk drive or a semiconductor memory, such as ROM or RAM.

An input section 50 is an input device, such as a touch pen, a keyboard or a mouse, and is operated by an operator to input various information or commands for layout design.

A floor display section 52 presents a visual display of input information and the layout diagram.

A control section 54 controls the floor display section 52, the automatic placement section 20, the global routing section 22, the detailed routing section 24, the wire congestion analysis section 30, the crosstalk noise analysis section 32 and the grid setting section 40.

In the first embodiment, a semiconductor integrated circuit whose wire pitches are so set as to meet the required routing completion time and the required crosstalk noise level is designed by using the design aiding apparatus 100.

The design process that is executed by the design aiding apparatus 100 will be discussed below.

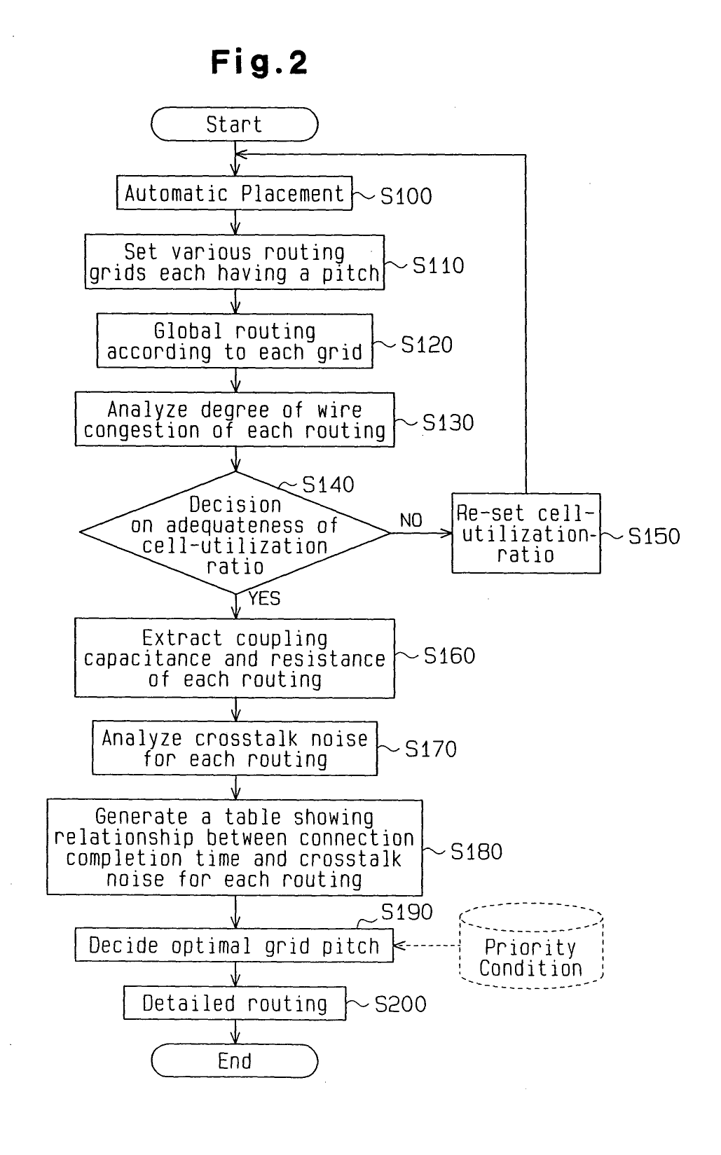

In step S100 in the flowchart in FIG. 2, the circuit information of the gate level stored in the design specification storage section 12 is input to the automatic placement section 20. The automatic placement section 20 performs automatic placement of functional cells based on the gate level circuit information and the cell-utilization-ratio set by the cell-utilization-ratio setting section 16. To reduce the area of the semiconductor integrated circuit, it is desirable that the cell-utilization-ratio be as large a value as possible within the empirically allowable range.

After placement of the functional cells, various routing grids each having a pitch are set in step S110. In step S120, trial routing process is performed with various routing grids having various wire pitches. The processes of steps S110 and S120 are preliminary processes for determining the adequate wire pitch in consideration of the correlation among the wire pitch, the routing completion time and the allowable range of crosstalk noise to ensure final wire connection within the desired routing completion time and the allowable range of crosstalk noise.

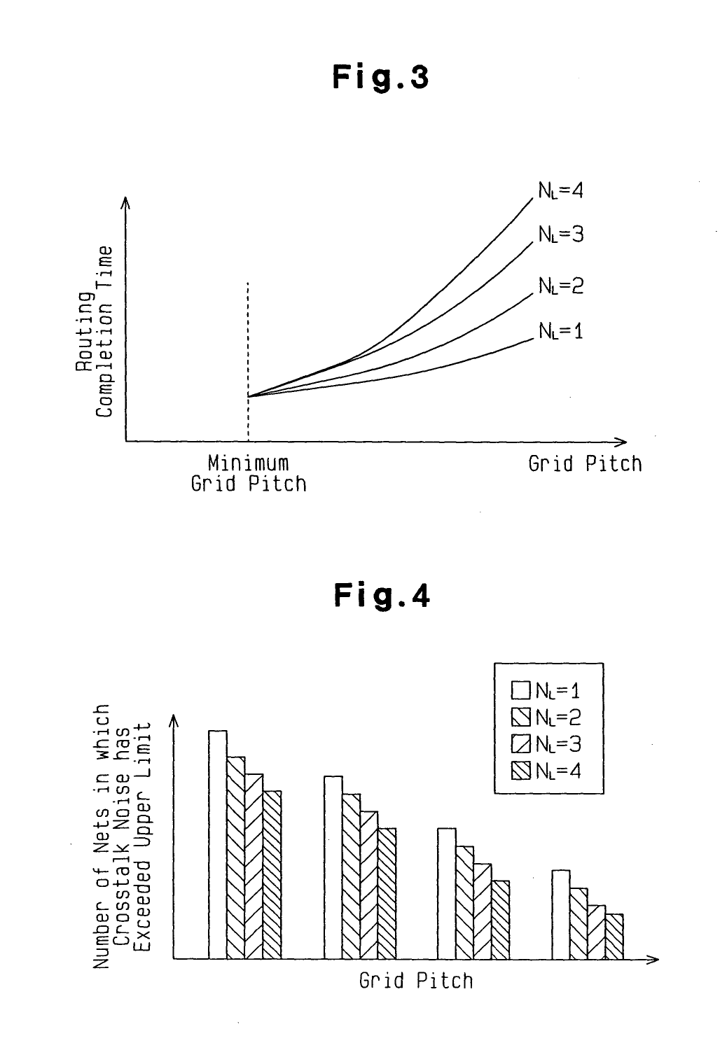

FIG. 3 is a graph showing the relationship between the pitch of routing grid lines and the routing completion time. The larger the pitch of routing grid lines, the smaller the available routing space or the routing resource, so that the routing completion time becomes longer. In the semiconductor integrated circuit having a multi-layer wire structure, as the number of wiring layers (N_{L}) to widen the pitch between the routing grid lines becomes larger, the routing resources are reduced, thus making the routing completion time longer.

The graph in FIG. 4 shows the relationship between the pitch of the routing grid lines and crosstalk noise. As the pitch of the routing grid lines becomes greater, the coupling capacitance generated between wires is reduced, thereby suppressing crosstalk noise. In the semiconductor integrated circuit having a multi-layer wire structure, therefore, as the number of wiring layers (N_{L}) to widen the pitch between the routing grid lines becomes larger, the crosstalk noise becomes lower.

Because of the correlation between the wire pitch and the routing completion time and the correlation between the wire pitch and crosstalk noise, the adequate wire pitch can be found by making trial routings at various wire pitches. After an adequate wire pitch is determined, detail connections are made. This can complete connections within the desired routing completion time while efficiently reducing crosstalk noise.

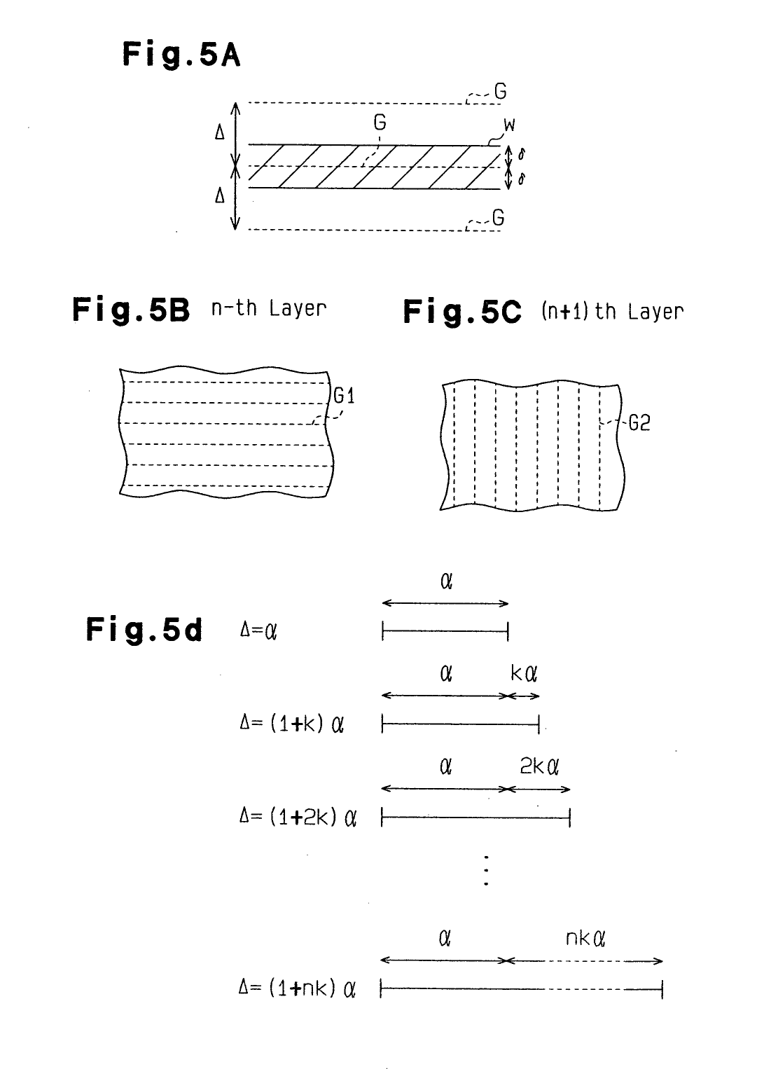

Specifically, in step S110, a plurality of routing grids which have various grid pitches are set. With regard to the grid in FIG. 5A, a plurality of routing grid lines G are parallel at a grid pitch Δ. The center axis of a wire W having a line width (2δ) (i.e., a straight line passing at the widthwise center position) is arranged on a single grid line G. That is, the grid line G is used to define the position of the wire W. In case of the semiconductor integrated circuit having a multi-layer wire structure, in each of the n-th layer and (n+1)th layer, grid lines G₁ or G₂ are parallel to each other at a predetermined pitch, as shown in FIGS. 5B and 5C. The grid lines G₁ and G₂ in adjacent layers are orthogonal to each other.

The pitch of the routing grid lines may vary from one layer to another. Specifically, as shown in FIG. 5D, the grid pitch Δ of each layer is the sum of a predetermined basic pitch α and an integer multiple of an auxiliary pitch kα smaller than the basic pitch α and is expressed by the following equation.

Δ=α+nkα=(1+nk)α

where

n=0, 1, 2, . . . , and k<1.

The basic pitch α is determined according to the minimum design-rule dimension of the fabrication process or the fabrication apparatus of the semiconductor integrated circuit (e.g., the minimum design-rule dimension of a lithography process).

In one embodiment, the grid pitch Δ is varied from the basic pitch α (a minimum value) to two times the basic pitch (2α) in a stepwise manner. For example, when the basic pitch α is 0.4 micrometers, k is 0.2 and n is varied from 0 to 5, the grid pitch Δ is widened from 0.40 micrometers, 0.48 micrometers, 0.56 micrometers, 0.64 micrometers, 0.72 micrometers, and 0.80 micrometers. The upper limit of the grid pitch Δ is not limited, and it is possible to use a grid pitch Δ greater than 2α.

In one embodiment, the lower limit of the grid pitch Δ is the minimum wire pitch that can be achieved by the fabrication apparatus. The degree of freedom of the layout design is improved by setting the grid pitch Δ, or the pitch of the center axes of adjacent wires W, not to be an integer multiple of the basic pitch α or not to be an integer multiple of the sum of the basic pitch α and the auxiliary pitch kα. Accordingly, widening the wire pitch to reduce crosstalk noise and suppression of an increase in the wire pitch to secure a routing resource can both be satisfied.

The auxiliary pitch kα is set in such a way that its the integer multiple becomes the basic pitch α. This ensures easier contact between wires of different wiring layers even if the grid pitch differs wiring layer by wiring layer.

The cell grid which is used by the automatic placement section 20 to define the cell layout preferably includes cross points or grid points of grid lines formed when two routing grids whose grid pitch Δ is set to the basic pitch α overlap each other in such a way as to be orthogonal to each other. Even in this case, the grid pitch Δ is set in such a way that an integer multiple of the auxiliary pitch kα becomes the basic pitch α. This allows the functional cells to be placed along the routing grid lines, thus making the connection of the functional cells easier.

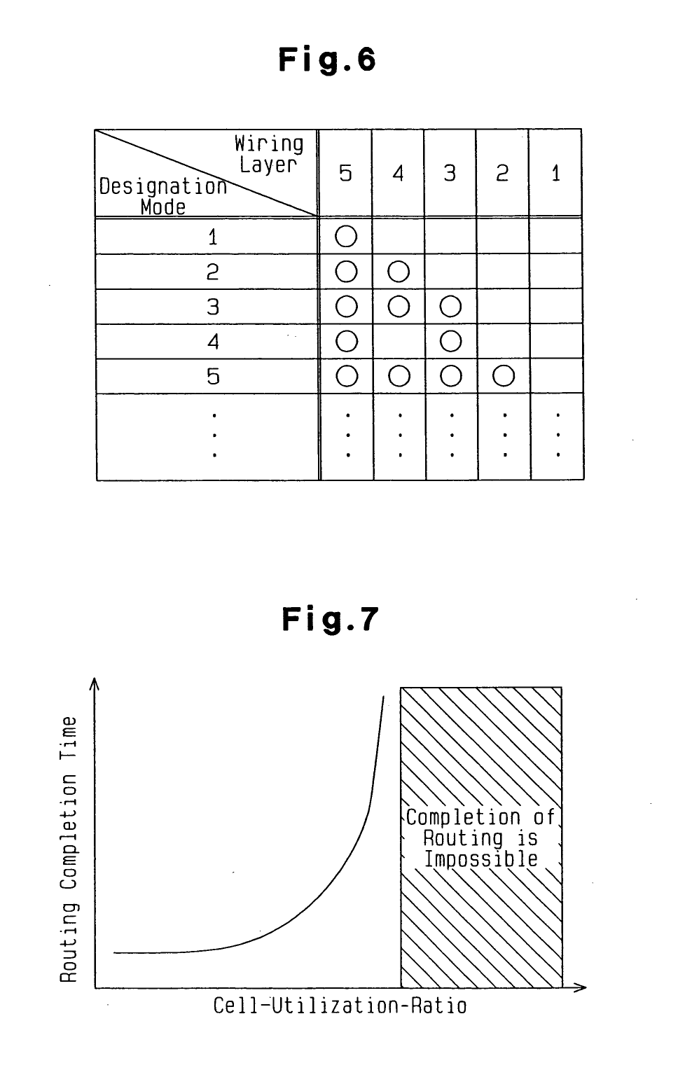

FIG. 6 indicates a wiring layer designation mode to specify how much the wire pitch of which one of a plurality of wiring layers should be widened. A wiring layer designation mode 1 designates the enlargement of the wire pitch of the fifth wiring layer. A wiring layer designation mode 2 designates the enlargement of the wire pitches of the fifth and fourth wiring layers. For example, a wiring layer 1 is the bottommost layer and the wiring layer 5 is the topmost layer.

It is desirable that the wiring layer designation modes 1 to 5 be determined so as to have a wider grid pitch for an upper layer by priority as shown in FIG. 6. In general, the “more upper” the layer is, the longer the lengths of parallel wires tend to become, so that the interlayer coupling capacitance tends to become larger for an upper wiring layer. It is therefore possible to effectively reduce the overall crosstalk noise of the semiconductor integrated circuit by increasing the wire pitch for an upper layer by priority.

In step S120, the global routing section 22 uses various grids with various grid pitches for each of a plurality of wiring layer designation modes. The global routing section 22 tentatively connects functional cells according to the wiring layer designation modes (FIG. 6) and grids to generate a plurality of trial routing data, respectively. In the trial routing, the wires are routed along the grid lines of each grid in such a way that the connection points are connected at, for example, the shortest distance. In the trial routing data, wires may overlap on the same grid, i.e., shorting of wires may occur, or there may be an unconnected portion remaining.

In step S130, the wire congestion analysis section 30 analyzes the degree of wire congestion for the plurality of trial routing data. The degree of wire congestion is defined quantitatively based on the number of shorted locations or the number of unconnected locations.

In step S140, the wire congestion analysis section 30 determines whether the cell-utilization-ratio set in step S100 is proper or not based on the upper limit of the degree of wire congestion. That is, the wire congestion analysis section 30 determines whether the cell-utilization-ratio analyzed in step S130 is equal to or smaller than the upper limit of the degree of wire congestion. It is desirable that the upper limit of the degree of wire congestion should be set for the value of each parameter which is a restriction of the design process for the semiconductor integrated circuit. The parameter is, for example, the minimum design-rule dimension that is determined according to the fabrication apparatus for the semiconductor integrated circuit.

When the analysis result exceeds the upper limit, the current cell-utilization-ratio is inadequate. In this case, the cell-utilization-ratio is set again to a smaller value in step S150. As shown in FIG. 7, as the cell-utilization-ratio becomes greater, the routing completion time becomes longer and when the cell-utilization-ratio is too large, completion of detailed routing is not possible. When the degree of wire congestion exceeds the predetermined upper limit, therefore, the cell-utilization-ratio is reduced to ensure the completion of detailed routing.

In the case where the cell-utilization-ratio is changed, the processes from step S100 to step S140 are repeated using the changed cell-utilization-ratio until the cell-utilization-ratio is decided to be adequate.

When it is determined in step S140 that the cell-utilization-ratio is adequate, the crosstalk noise analysis section 32 performs processing of steps S160 and S170. The processing of steps S160 and S170 analyze crosstalk noise.

Specifically, in step S160, the crosstalk noise analysis section 32 extracts the coupling capacitance between adjacent wires, the coupling capacitance between the wire and substrate and the wire resistance from the layout databases 10, 12 and 14. More specifically, the coupling capacitance and wire resistance are computed for each of the trial routing data which are laid out and generated by the automatic placement section 20 and the global routing section 22 by using process parameters stored in the process parameter storage section 14. For the coupling capacitance of shorted wires, the coupling capacitance of the wires separated by the wire pitch corresponding to the minimum grid pitch (basic pitch α) is used.

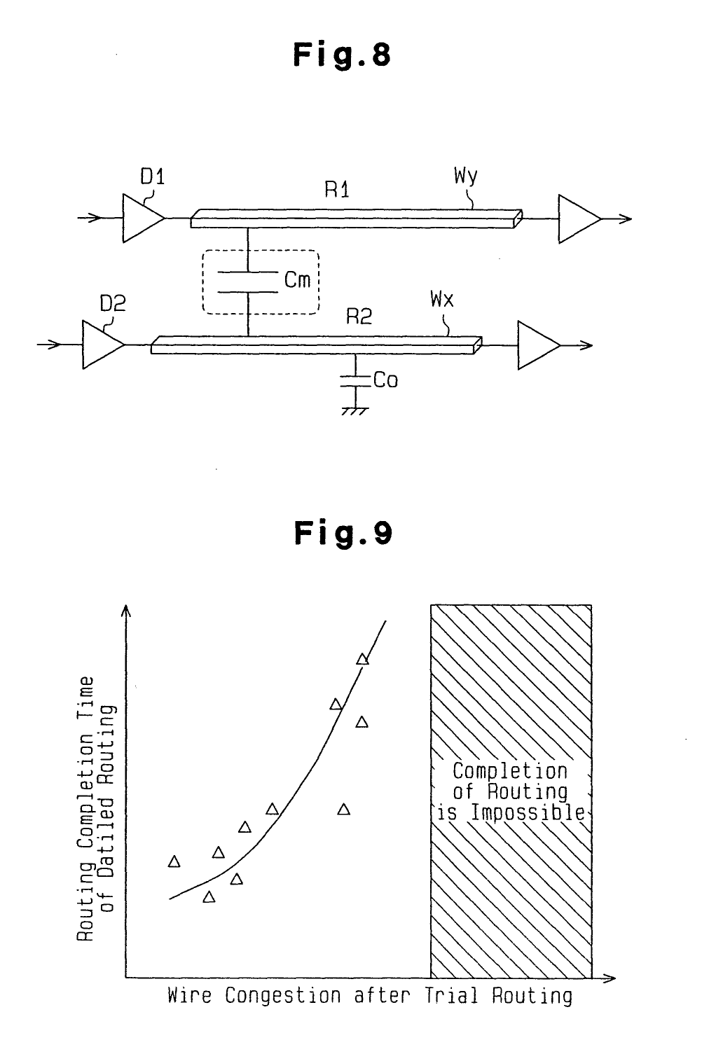

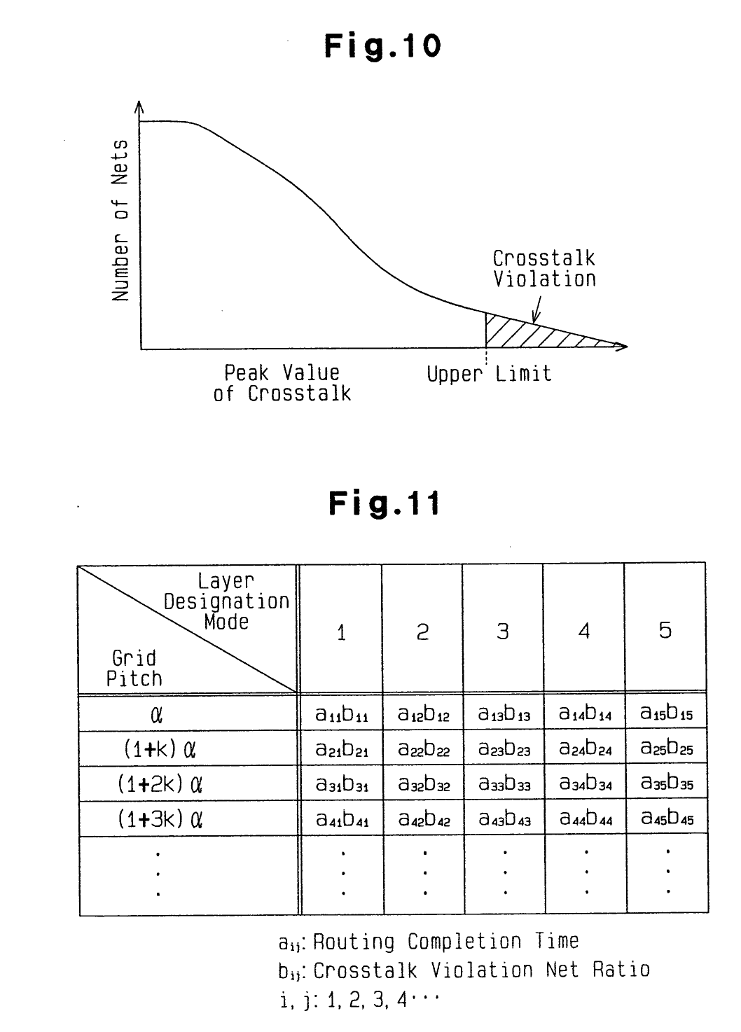

In step S170, the crosstalk noise analysis section 32 computes the crosstalk noise of each wire for each routing of the plurality of trial routing data. As shown in FIG. 8, with respect to a wire Wx to be subjected to calculation, for example, the crosstalk noise analysis section 32 performs:

(i) extracting a coupling capacitance Co between the wire Wx and the substrate, a coupling capacitance Cm between the wire Wx and an adjacent wire Wy, a wire resistance R2 of the wire Wx, a wire resistance R1 of the adjacent wire Wy by referring the process parameter storage section 14;

(ii) calculating the drive performance of a driver D1 which drives the adjacent wire Wy and the drive performance of a driver D2 which drives the target wire Wx by using the extracted values and by referring the library 10; and

(iii) calculating the timings for driving the drivers by referring to the process parameter storage section 14 to compute crosstalk noise which is produced on the target wire Wx as a voltage value or the ratio of a noise voltage to the system voltage of the semiconductor integrated circuit.

After the analysis of the crosstalk noise, the grid setting section 40 determines the optimal grid based on the result of analysis of the degree of wire congestion in step S130 and the result of analysis of the crosstalk noise in step S170.

Specifically, the grid setting section 40 predicts the time needed for the detailed routing section 24 to complete the detailed routing, for the plurality of trial routing data, based on the result of analysis of the degree of wire congestion in step S130 and referring to the database 42.

FIG. 9 shows data stored in the database 42. The greater the degree of wire congestion of the trial routing data, the longer the routing completion time. It is desirable that the database 42 should have data classified for each parameter value which is a restriction of the design process for the semiconductor integrated circuit. Restrictive parameters for the semiconductor integrated circuit include the minimum design-rule dimension that restricts the fabrication of the semiconductor integrated circuit, the total area of the semiconductor substrate and the cell-utilization-ratio. The data stored in the database 42 is acquired by obtaining the correlation between the degree of wire congestion and the routing completion time of the trial routing data through a test conducted beforehand by using sample data.

In step S180, provided that the detailed routing section 24 has completed routing based on the plurality of trial routing data, the grid setting section 40 predicts crosstalk noise which is produced in the virtual integrated circuit based on the result of analysis of the crosstalk noise in step S170 and referring to the database 44. Specifically, the grid setting section 40 computes the ratio of a net which results in the violation of crosstalk noise that exceeds the upper limit of the crosstalk noise (crosstalk noise violation ratio) from the result of analysis of the crosstalk noise. Then, the grid setting section 40 predicts the crosstalk noise violation ratio of the net for the virtual integrated circuit using the computed ratio and data in the database 44. It is desirable that the database 44 have data classified for each parameter value which is a restriction of the design process for the semiconductor integrated circuit. The data stored in the database 44 is acquired by obtaining the correlation between the crosstalk noise of a tentatively connected semiconductor integrated circuit and the crosstalk noise of the virtual integrated circuit whose routing has been completed through a test conducted beforehand by using sample data.

Next, the grid setting section 40 generates table data indicating the predicted routing completion time and predicted crosstalk noise violation ratio. The table data in FIG. 11 shows the predicted routing completion time and predicted crosstalk noise violation ratio for the plurality of trial routing data. In case of trial routing data whose wiring layer designation mode is 1 and grid pitch Δ is set to α, for example, the routing completion time is a₁₁ and the crosstalk violation net ratio is b₁₁.

In step S190, the grid setting section 40 determines the optimal grid. Specifically, the designer inputs the degree of priority (priority condition: FIG. 1) of the routing completion time and the crosstalk noise measure to the design aiding apparatus 100 via the input section 50. The grid setting section 40 searches for the most desirable trial routing data based on the priority condition and the table data in step S180 and determines the optimal grid.

The maximum allowable peak value of the crosstalk noise or the longest allowable routing completion time may also be input in addition to the degree of priority. In the case where the priority is given to crosstalk noise measure, therefore, the grid that can suppress the crosstalk noise most within the longest allowable routing completion time is selected. In the case where the priority is given to the routing completion time, the grid that has the shortest routing completion time within the maximum allowable peak value of crosstalk noise is selected.

It is preferable that the degree of priority be quantized using a cost function. The cost function includes a process for giving a predetermined weight to the connection time and the crosstalk noise violation net ratio and adding or multiplying the weighted connection time or the connection time cost and the weighted crosstalk noise violation net ratio or the crosstalk noise cost together or by each other. The grid that has the minimum value after the cost function process is the grid that matches the designated degree of priority the most.

The value of the weight quantitatively indicates the degree of priority. For example, as the weighting of the crosstalk noise is set greater than the weighting of the connection time, the suppression of crosstalk noise has priority over the connection time. In this case, an increase in crosstalk noise violation net ratio significantly increases the value after the cost function process, so that the value of the cost function process cannot become the minimum. Therefore, the grid that corresponds to the trial routing data which has a smaller crosstalk noise violation net ratio is the grid that matches the designated degree of priority the most.

After the optimal grid is decided, the detailed routing section 24 performs the detail connection process in step S200.

The process time required for the detail connection process may be additionally registered in the database 42 in association with the degree of wire congestion of the grid analyzed in step S130. The crosstalk noise of the integrated circuit after the detail connection process may be analyzed and the analysis result may be additionally registered in the database 44 in association with the result of the analysis on the crosstalk noise of the grid in step S170. Updating the databases 42 and 44 this way improves the precision of the subsequent prediction.

The first embodiment has the following advantages.

(1) As the routing grid pitch or the distance of the center axes of the wires is settable to an integer multiple of the basic pitch α or a pitch which is not an integer multiple of the basic pitch α, the degree of freedom for wire connection can be increased. This can satisfy both widening the wire pitch to reduce the crosstalk noise and suppression of the wire pitch to secure routing resources.

(2) The grid pitch Δ is set in such a way that the grid pitch Δ is the sum of the basic pitch α and a predetermined integer multiple of the auxiliary pitch kα smaller than the basic pitch α or Δ=α+nka (n=0, 1, 2, . . . and k<1) and the integer multiple of the auxiliary pitch kα becomes the basic pitch α. This can allow wires of different wiring layers to be connected easily even if the grid pitch differs from one wiring layer to another.

(3) The grid pitch is set independently for each wiring layer. As the grid pitch suitable for each wiring layer is set, the crosstalk noise is efficiently reduced.

(4) A trial routing process is carried out after placing functional cells. The degree of wire congestion for the trial routing data is analyzed. Based on the analysis result, the time required for the detailed routing section 24 to perform the connection process is predicted. As the time needed for wire connection is predicted before final connection, an adequate wire pitch that can satisfy the required connection process time can be acquired earlier.

(5) The correlation between the degree of wire congestion of the trial routing data and the connection process time needed by the detailed routing section 24 is stored in the database 42. Based on the result of analyzing the degree of wire congestion for the trial routing data, therefore, it is possible to suitably predict the routing completion time for the semiconductor integrated circuit.

(6) A trial routing process is executed after placing functional cells. The crosstalk noise of the trial routing data is analyzed. Based on the analysis result, the crosstalk noise which will occur after wire connection by the detailed routing section 24 is predicted. As the crosstalk noise of the semiconductor integrated circuit is predicted before final connection, the wire pitch that can suppress the crosstalk noise to the allowable range can be acquired earlier.

(7) The correlation between the result of analysis on the crosstalk noise of the trial routing data and the crosstalk noise of the semiconductor integrated circuit after wire connection by the detailed routing section 24 is stored in the database 44. Based on the result of analyzing the crosstalk noise of the trial routing data, the crosstalk noise of the semiconductor integrated circuit after completion of the detailed routing can suitably be predicted.

(8) The pitch of the wires that connect functional cells (grid pitch Δ) is set to a plurality of values, the functional cells are tentatively connected with plural wire pitches and the routing completion time and crosstalk noise for each wire pitch are predicted. Based on the prediction result, a plurality of trial routing data are evaluated and the optimal routing data is determined. It is therefore possible to acquire, before final wire connection, the optimal wire pitch that can ensure wire connection and can satisfy both the required routing completion time and the required crosstalk noise.

(9) It is determined based on the degree of wire congestion whether or not the completion of the detailed routing process is possible and if such is not possible, the cell-utilization-ratio is reduced so that the detailed routing process for the functional cells can surely be completed.

(10) As the pitch between the center axes of the wires is set to an integer multiple of a predetermined minimum pitch for each wiring layer, the control program for the automatic routing tool which performs the connection process is simplified and the connection process by the automatic routing tool can be carried out in a short period of time.

The following will discuss a semiconductor integrated circuit according to a second embodiment of the invention and a design method therefor, centering on what differs from the first embodiment.

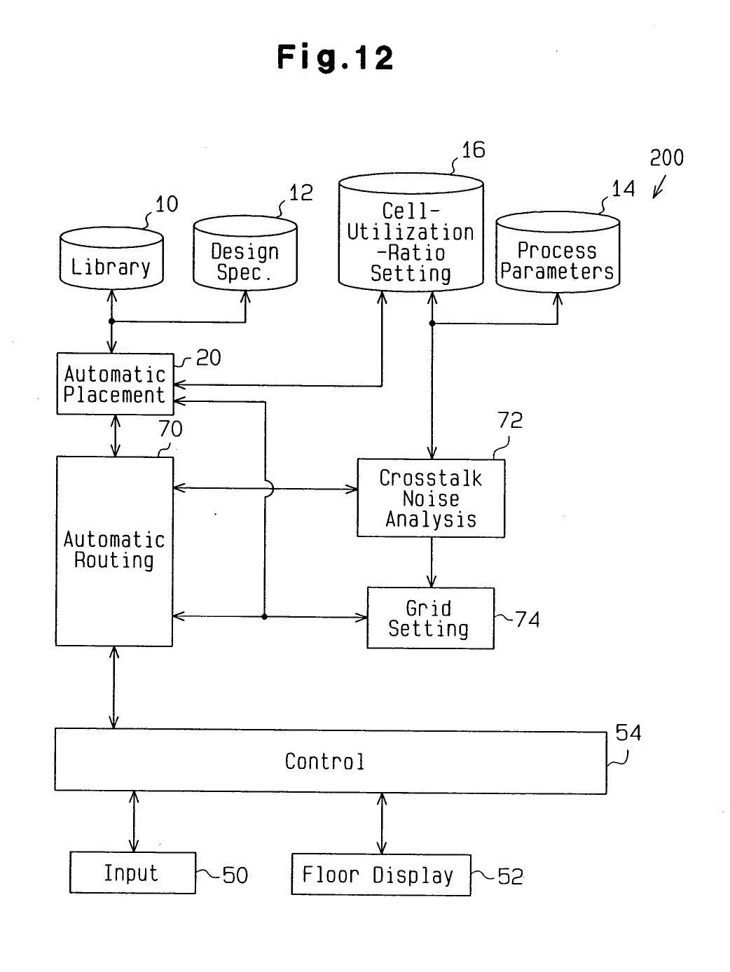

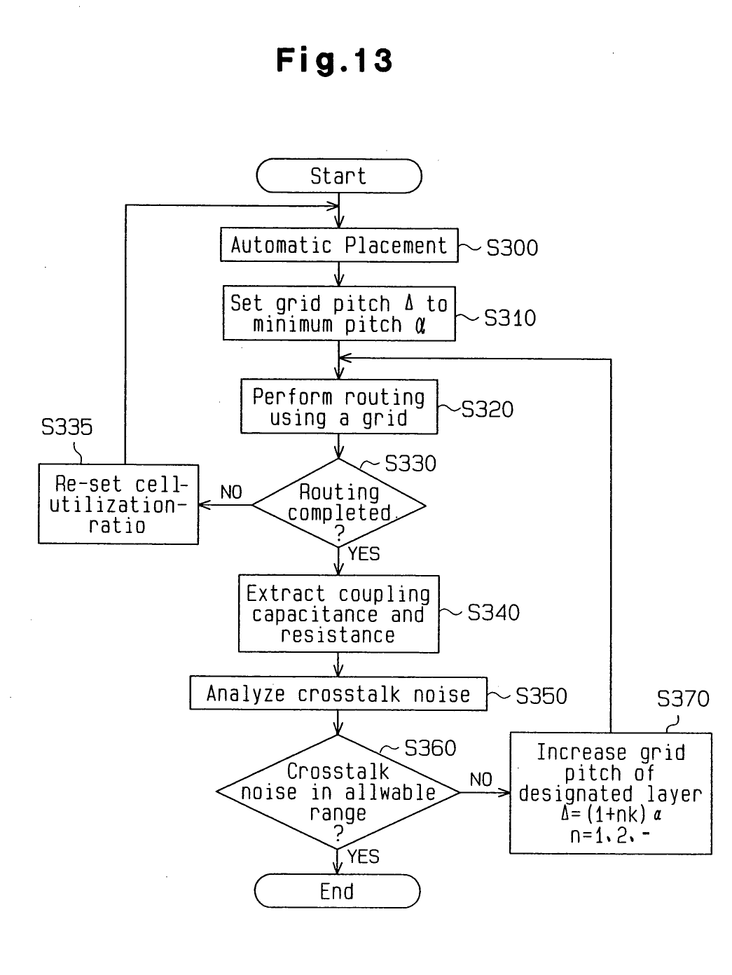

FIG. 12 is a block diagram of a design aiding apparatus 200 according to the second embodiment. In FIG. 12, same or like reference symbols are given to those components which are the same as the corresponding components in FIG. 1 for the sake of convenience. FIG. 13 is a flowchart illustrating the design process for a semiconductor integrated circuit including a connection process for functional cells, which is carried out by the design aiding apparatus 200.

The design process for a standard cell type semiconductor integrated circuit will be discussed as one example. First, the automatic placement section 20 automatically places functional cells based on the circuit information of the gate levels and the cell-utilization-ratio set by the cell-utilization-ratio setting section 16. It is desirable that the cell-utilization-ratio be as large a value as possible within the empirically allowable range in order to reduce the area of the semiconductor integrated circuit.

In step S310, a grid setting section 74 sets the grid pitch Δ that defines the pitch of wires which connect functional cells to the basic pitch α.

In step S320, an automatic routing tool or an automatic routing section 70 performs a connection process for functional cells using the grid with the grid pitch Δ.

In step S330, the automatic routing section 70 determines if the routing process has been completed. When the routing process is not completed even after a predetermined time elapses, for example, the automatic routing section 70 decides that the completion of the routing process is impossible. When it is determined in step S330 that the completion of the routing process is not possible (NO), the automatic routing section 70 reduces the cell-utilization-ratio in step S335 as done in step S150 in FIG. 2. Then, the processing of steps S300 to S335 are repeated until the routing process is completed or it is decided that the routing of the connection process is possible.

In step S340, after the completion of the routing process, a crosstalk noise analysis section 72 extracts the coupling capacitance between adjacent wires, the coupling capacitance between the wires and the substrate and the wire resistance from the layout databases 10, 12 and 14. Specifically, the coupling capacitance and wire resistance of the trial routing data are computed using process parameters stored in the process parameter storage section 14 in addition to the trial routing data laid out by the automatic placement section 20 and the automatic routing section 70.

In step S350, the crosstalk noise analysis section 72 computes the crosstalk noise of the trial routing data (see FIG. 8).

In step S360, the crosstalk noise analysis section 72 determines whether or not the crosstalk noise lies in the allowable range. The allowable range of the crosstalk noise is determined beforehand in such a way that the logical inversion of the output logical signal of a sequential logic circuit does not occur and the deviation of the actual operational frequency from the desired operational frequency of the semiconductor integrated circuit caused by a change in signal propagation speed is in an allowable range.

In the case where the crosstalk noise is out of the allowable range (NO in step S360), the grid pitch Δ of a layer is increased in step S370. The increased grid pitch Δ is the sum of the basic pitch α and a predetermined integer multiple of the auxiliary pitch kα smaller than the basic pitch α and is expressed by the following equation.

Δ=α+nkα(n=0, 1, 2, . . . , and k<1)

The basic pitch α is set based on the minimum design-rule dimension of the fabrication process of the semiconductor integrated circuit (the minimum design-rule dimension of a lithography process), as per the first embodiment. The integer multiple of the auxiliary pitch kα coincides with the basic pitch α.

In step S370, it is desirable to increase the grid pitch Δ of an upper wiring layer by priority. The grid pitches Δ of all the wiring layers may be increased.

In step S360, steps S320 to S370 are repeated until crosstalk noise falling in the allowable range is obtained.

When crosstalk noise falling in the allowable range is obtained (YES in step S360), the process shown in FIG. 13 is terminated.

The second embodiment also has the advantages (1) to (3) and (9) of the first embodiment.

The following will discuss a semiconductor integrated circuit according to a third embodiment of the invention and a design method therefor, centering on what differs from the first embodiment.

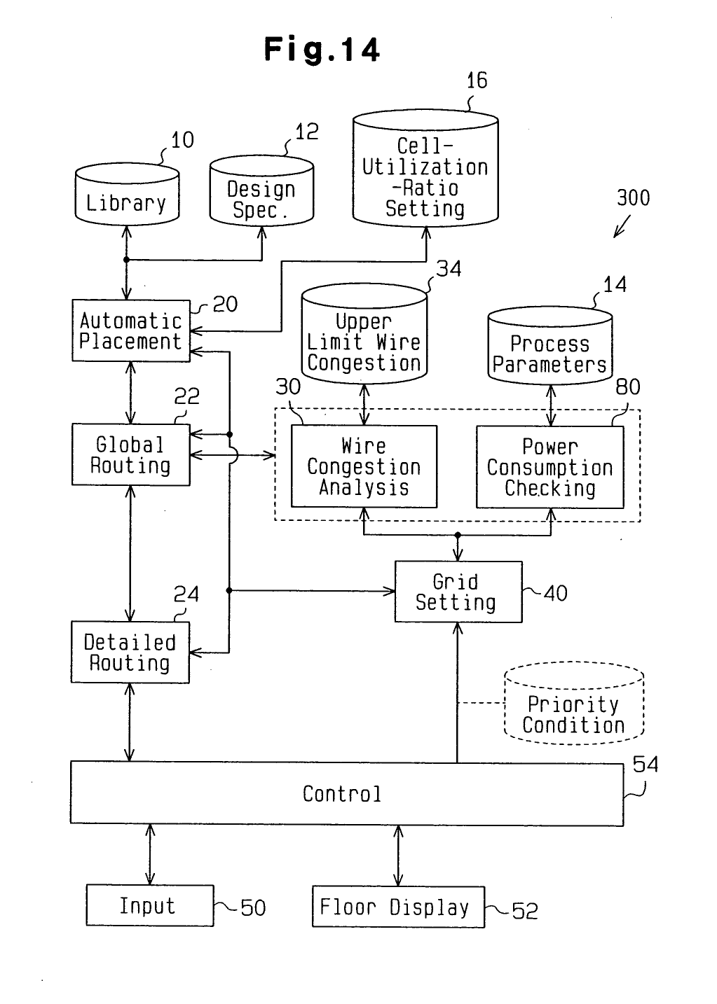

FIG. 14 is a block diagram of a design aiding apparatus 300 according to the third embodiment. In FIG. 14, same or like reference symbols are given to those components which are the same as the corresponding components in FIG. 1 for the sake of convenience.

In the first embodiment, the wire pitch that satisfies the requirements for both the routing completion time and the crosstalk noise is set. According to the third embodiment, by way of contrast, the wire pitch that satisfies the requirements for both the routing completion time and the power consumption is set. Accordingly, the design aiding apparatus 300 shown in FIG. 14 has a power consumption checking section 80 in place of the crosstalk noise analysis section 32 in FIG. 1. The design aiding apparatus 300 according to the third embodiment directly uses the degree of wire congestion of the trial routing data as a parameter for computing the routing completion time. That is, because of the correlation between the degree of wire congestion of the trial routing data and the routing completion time as shown in FIG. 9, the upper limit of the routing completion time is indirectly designated by designating the upper limit of the degree of wire congestion.

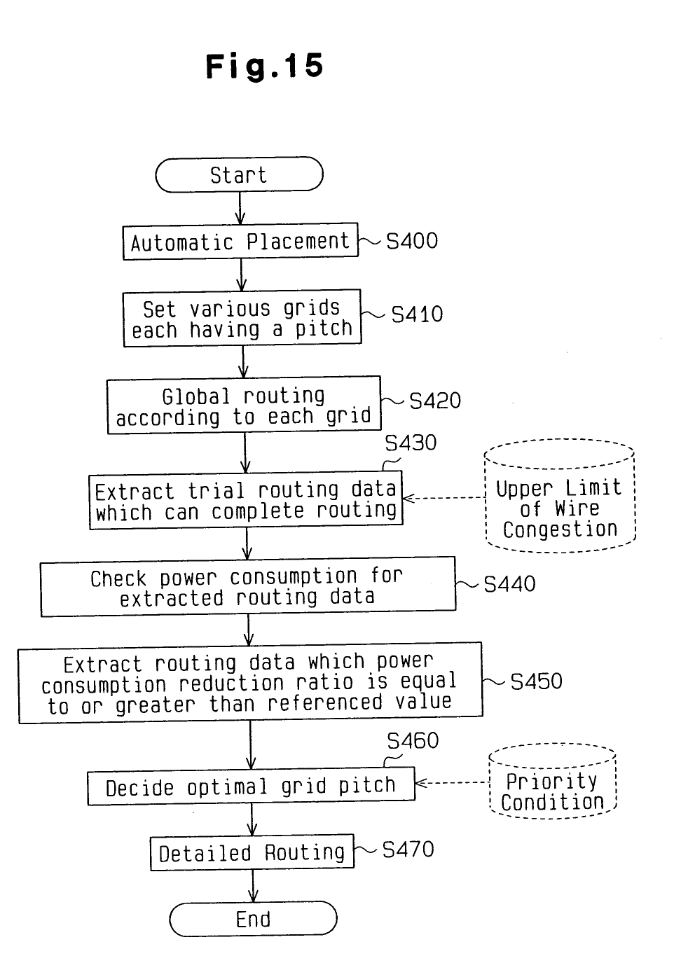

FIG. 15 illustrates a design process for a semiconductor integrated circuit, which includes the determination of the wire pitch and the connection process for functional cells and is executed by the design aiding apparatus 300.

Steps S400 to S420 are the same as steps S100 to S120 in FIG. 2.

In step S430, trial routing data which can complete routing is extracted from the plurality of the trial routing data tentatively generated using a plurality of grids. The extraction is performed based on information acquired from the trial routing data.

Specifically, the wire congestion analysis section 30 analyzes the degrees of wire congestion of the plurality of trial routing data as done in step S130 in FIG. 2. The trial routing data whose analyzed degrees of wire congestion are equal to or smaller than the upper limit are stored in the upper-limit wire congestion storage section 34. Those trial routing data can complete wire connection.

In step S440, the power consumption checking section 80 computes total power consumption of wires for each of the extracted trial routing data. In the following description, the term “power consumption” refers to the total of the power consumption of the individual wires. The power consumption of each wire can be computed from the degree of charge/discharge of each wire. For example, based on the fact that the degree of charge/discharge is associated with a coupling capacitance C between the wire and another wire, a drive voltage V of the wire, the operational frequency f of a circuit associated with the wire or a transition probability β of a signal which flows in the wire, the power consumption of each wire can be computed from the following equation:

Power consumption=βCVf²×proportional constant

The transition probability β is acquired based on, for example, circuit information of the trial routing data. That is, the transition probability β of the signal on each wire when the integrated circuit corresponding to the trial routing data is operated in a test mode is acquired based on the circuit information of the trial routing data. The transition probability β is defined as the number of transitions of the signal level per pitch clock, for example.

In step S450, the power consumption checking section 80 extracts trial routing data whose ratio of power consumption to predetermined power consumption or power consumption reduction ratio is equal to or greater than a reference value. The predetermined power consumption is, for example, the power consumption of a past product similar to the target semiconductor integrated circuit or the maximum value of the power consumptions computed in step S440.

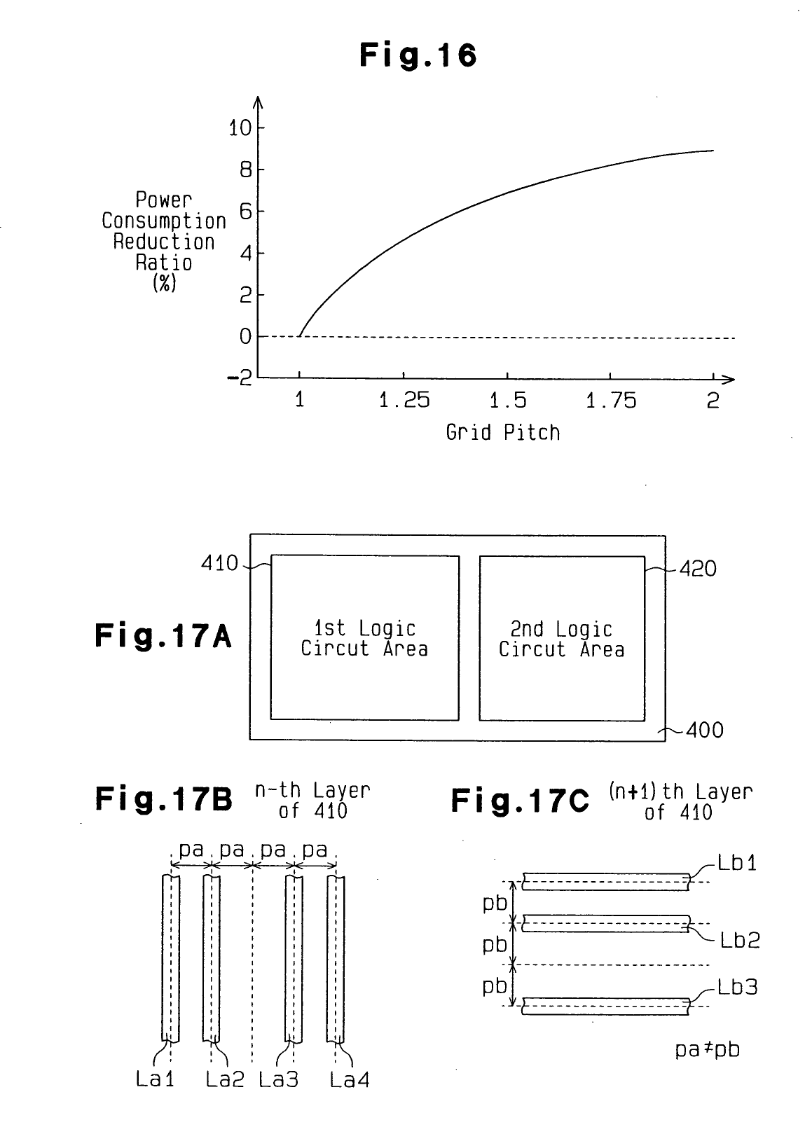

The graph in FIG. 16 shows the relationship between the grid pitch and the power consumption. The vertical axis shows a ratio of a change with respect to the power consumption when the grid pitch (arbitrary scale) of 1 being a reference. The wider the grid pitch of the grid used to generate trial routing data, the lower the interlayer coupling capacitance, resulting in lower power consumption.

In step S460, the grid setting section 40 selects the optimal one of the trial routing data extracted in step S450. The grid that is used in generating the selected trial routing data is selected as the optimal grid. In this process, as in step S190 in FIG. 2, the designer inputs the degree of priority (priority condition) between the routing completion time and the power consumption to the design aiding apparatus 300 via the input section 50. Based on the priority condition, the grid setting section 40 determines the optimal grid. The degree of priority may be quantized using a cost function.

After determination of the optimal grid, the detailed routing section 24 performs detail wire connection in step S470.

The third embodiment has the following advantages in addition to the advantage (2) of the first embodiment.

(11) As the routing grid pitch or the pitch of the center axes of the wires is set to an integer multiple of the basic pitch α or a pitch which is not an integer multiple of the basic pitch α, the degree of freedom for wire connection is increased. This can satisfy both widening the wire pitch to reduce the power consumption and increasing the wire pitch to secure routing resources.

(12) The grid pitch is set for each wiring layer. Accordingly, the power consumption is reduced efficiently.

(13) A trial routing process is carried out after placing functional cells, and the degree of wire congestion for the trial routing data is analyzed. Based on the analysis result, the time required for the detailed routing section 24 to perform the connection process is computed. This can allow the routing completion time to be predicted before completion of detailed routing, so that the adequate wire pitch which can ensure completion of wire connection can be acquired earlier.

(14) A trial routing process is carried out after placing functional cells, and total power consumption of wires of the trial routing data is computed. The total power consumption of the wires of the trial routing data is used to evaluate the power consumption of the integrated circuit whose routing has been completed. As the power consumption of the final integrated circuit can be evaluated using trial routing data, the wire pitch that can suppress the power consumption within the allowable range can be acquired in a relatively short time.

(15) Temporary wire connection is carried out with various wire pitches and the routing completion time and power consumption are predicted for each wire pitch. Accordingly, the wire pitch that can ensure wire connection while satisfying the requirements for the routing completion time and power consumption can be determined prior to completion of detailed routing.

A semiconductor integrated circuit 400 fabricated according to the design method of the invention will be discussed below.

FIG. 17A is a top view of the semiconductor integrated circuit 400. The semiconductor integrated circuit 400 has a first logic circuit area 410 where logic circuits are formed and a second logic circuit area 420 where another logic circuits are formed. The first logic circuit area 410 is the area that is designed and fabricated according to the design method of each embodiment. The following description is for a case in which the minimum design-rule dimensions for fabricating the n-th layer and the (n+1)th layer of the first logic circuit area 410 are equal.

FIG. 17B shows wires La1 to La4 of the n-th wiring layer of the first logic circuit area 410. The wires La1 to La4 of the n-th wiring layer are substantially parallel to one another and the pitch of the center axes of the wires La1 to La4 is set to an integer multiple of a predetermined minimum pitch pa. The pitch between the wires La1 and La2 and the pitch between the wires La3 and La4 are the minimum pitch pa. The pitch between the wires La2 and La3 is twice the minimum pitch pa.

FIG. 17C shows wires Lb1 to Lb4 of the (n+1)th wiring layer of the first logic circuit area 410. The wires Lb1 to Lb4 of the (n+1)th wiring layer are substantially parallel to one another and the pitch of the center axes of the wires Lb1 to Lb4 is set to an integer multiple of a predetermined minimum pitch pb which is greater than pa. The pitch between the wires Lb1 and Lb2 is the minimum pitch pb. The pitch between the wires Lb2 and Lb3 is twice the minimum pitch pb.

The relationship between the minimum pitches pa and pb will be discussed below.

In the examples in FIGS. 17A to 17C, as the grid pitch Δ can be set for each wiring layer, the minimum pitch pa of the n-th wiring layer differs from the minimum pitch pb of the (n+1)th wiring layer. In the case where the pitches of the center axes of the wires of all the wiring layers in the integrated circuit are set equal (pa=pb), however, an equal grid pitch should be used for all the wiring layers in designing the integrated circuit.

The minimum pitch pa and the minimum pitch pb of the (n+1)th wiring layer can be set in such a way that one of the minimum pitches does not become an integer multiple of the other. This is possible because the grid pitch Δ is set to the sum (+α+nkα) of the basic pitch α and an integer multiple of the auxiliary pitch kα. In the case where the grid pitch Δ is set to an integer multiple of the basic pitch α, on the other hand, one of the minimum pitches pa and pb always becomes an integer multiple of the other.

The minimum design-rule dimension in the fabrication process for a semiconductor integrated circuit having a multi-layer wire structure should not necessarily be the same for all the wiring layers according to the materials and the planarization of the interlayer insulation film. For example, the minimum design-rule dimensions of the individual wiring layers in a semiconductor integrated circuit having five wiring layers may be set in such a way that the minimum design-rule dimension is the smallest for the first (lowest) wiring layer, takes a common value for the second to fourth wiring layers and is the largest for the fifth (topmost) wiring layer. Because the minimum pitch pb for the (n+1)th layer, for example, is set to such a pitch which does not become an integer multiple of the minimum design-rule dimension in the semiconductor integrated circuit 400, the degree of freedom of setting the wire pitches of the semiconductor integrated circuit 400 is high. Therefore, the semiconductor integrated circuit 400 is so designed as to satisfy various demands.

In the case where the first and second logic circuit areas 410 and 420 are designed in accordance with the present invention, the minimum pitch pb of the (n+1)th layer of the first logic circuit area 410 may be equal to the minimum design-rule dimension while the minimum pitch (pc) of the (n+1)th layer of the second logic circuit area 420 may differ from an integer multiple of the minimum design-rule dimension. In this case, the minimum pitch pc of the second logic circuit area 420 may also differ from an integer multiple of the minimum pitch pb of the first logic circuit area 410.

It should be apparent to those skilled in the art that the present invention may be embodied in many other specific forms without departing from the spirit or scope of the invention. Particularly, it should be understood that the present invention may be embodied in the following forms.

The database 42 may store prediction data obtained by computing the correlation between the degree of wire congestion and the routing completion time according to an adequate relational equation.

The routing completion time may be predicted without using the database 42 but by computing the correlation between the degree of wire congestion and the routing completion time according to an adequate relational equation.

The database 44 may store prediction data obtained by computing the correlation between the crosstalk noise after temporary wire connection and the crosstalk noise after completion of routing according to an adequate relational equation.

The crosstalk noise after completion of routing may be predicted without using the database 44, but by computing the correlation between the crosstalk noise after temporary wire connection and the crosstalk noise after completion of routing according to an adequate relational equation.

The routing completion time may be predicted without using the database 44 but by computing the correlation between the degree of wire congestion and the routing completion time according to an adequate relational equation.

The mode of analysis of the crosstalk noise and the mode of setting the upper limit of the crosstalk noise are not limited to those of the above-described embodiments.

In the first embodiment, the advantages (1) to (8) can be provided without performing the process of re-setting the cell-utilization-ratio but by placing functional cells using the adequate cell-utilization-ratio set beforehand.

In the first embodiment, the optimal grid may be selected in the following manner. First, one grid is set. Temporary wire connection is carried out using this grid and the degree of wire congestion and crosstalk noise of the trial routing data are checked. Based on the checking results, the routing completion time and the crosstalk noise after completion of detailed routing are predicted. Based on the prediction results, it is determined whether or not the grid is adequate to complete the routing. If the grid is improper, the grid is changed and a sequence of processes is repeated. The repetition of the processes provides the optimal grid or the optimal wire pitch faster. In this case, the first grid may have the minimum grid pitch. It is preferable that the grid pitch should be increased step-by-step.

In the first embodiment, the routing completion time may not be predicted from the degree of wire congestion of the trial routing data. In this case, the wire pitch that can suppress the crosstalk noise within the allowable range is obtained before completing the detailed routing by predicting the crosstalk noise after completion of the detailed routing based on the crosstalk noise of the trial routing data.

In the first embodiment, the crosstalk noise upon completion of detailed routing may not be predicted based on the crosstalk noise of the trial routing data. In this case, the wire pitch that can finish the wire connection within the desired period of time before completing the detailed routing by predicting the routing completion time from the degree of wire congestion of the trial routing data.

In the case where the grid pitch is increased for a plurality of wiring layers, the amount of the increase in grid pitch may differ wiring layer by wiring layer.

In step S370 in the second embodiment, the grid pitches of a plurality of wiring layers may be adequately changed instead of increasing the grid pitch of a given wiring layer step-by-step.

The advantages (1) to (3) can be provided without performing the process of re-setting the cell-utilization-ratio in step S335 in the second embodiment but by setting the adequate cell-utilization-ratio set beforehand.

In the third embodiment, the optimal grid may be selected in the following manner. First, one grid is set. Temporary wire connection is carried out using this grid and the degree of wire congestion and power consumption of the trial routing data are checked. Based on the results from the check, the routing completion time and the power consumption after completion of detailed routing are predicted. Based on the prediction results, it is determined whether or not the grid is adequate to complete the detailed routing. If the grid is not improper, the grid is changed and a sequence of processes is repeated. The repetition of the processes provides the optimal grid or the optimal wire pitch faster. In this case, the first grid may have the minimum grid pitch. It is preferable that the grid pitch should be increased step-by-step.

In the third embodiment, the routing completion time may not be predicted simply from the degree of wire congestion of the trial routing data. In this case, the wire pitch that can suppress at least the power consumption within the allowable range is obtained before completing the detailed routing by predicting the power consumption upon completion of the detailed routing based on the power consumption of the trial routing data.

In the third embodiment, as per the second embodiment, after wire connection is made with a predetermined grid pitch without making temporary wire connection, the power consumption of the connected integrated circuit may be evaluated, and when this power consumption is off the allowable range, the grid pitch of a given wiring layer may be increased step-by-step. Instead of the step-by-step increase in the grid pitch of a given wiring layer, the grid pitches of a plurality of wiring layers may be adequately changed.

In the third embodiment, the n-th power of the connection time T may be treated as a connection time cost.

In consideration of wasteful power consumption becoming larger as the crosstalk noise gets larger, the result of analyzing the crosstalk noise may be used in computing the power consumption.

Information which is acquired from trial routing data is not limited to the degree of wire congestion, the crosstalk noise and the power consumption. Any type of information is usable which can be the index to evaluate if the trial routing data satisfies the required items.

The requirements for the integrated circuit to be designed are not limited to a phenomenon relating to the coupling noise, such as the crosstalk noise or power consumption, and the degree of wire congestion. For example, the precision of the operational timing may be one requirement. There may be a plurality of requirements, such as the combination of the crosstalk noise and power consumption.

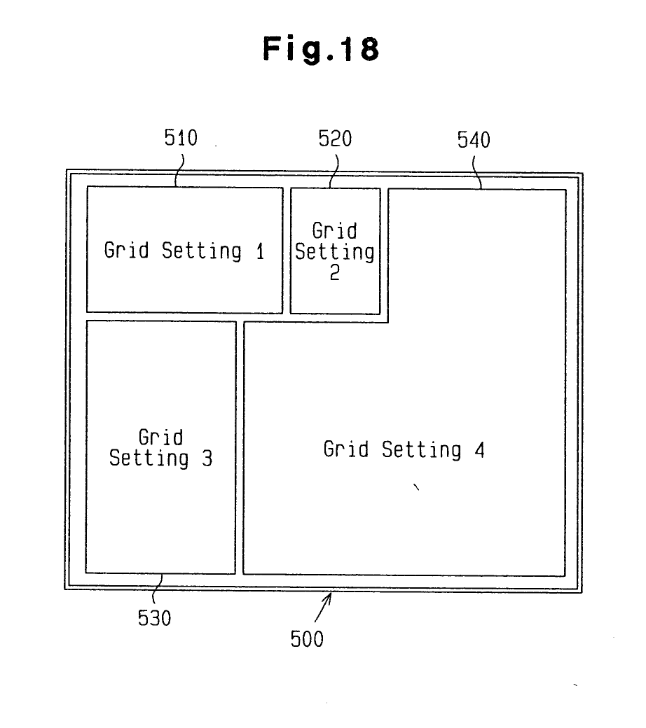

The grid pitch may differ for each functional block having a predetermined function. For instance, a semiconductor integrated circuit 500 in FIG. 18 has four functional blocks 510, 520, 530 and 540 which respectively have different grid pitches 1, 2, 3 and 4.

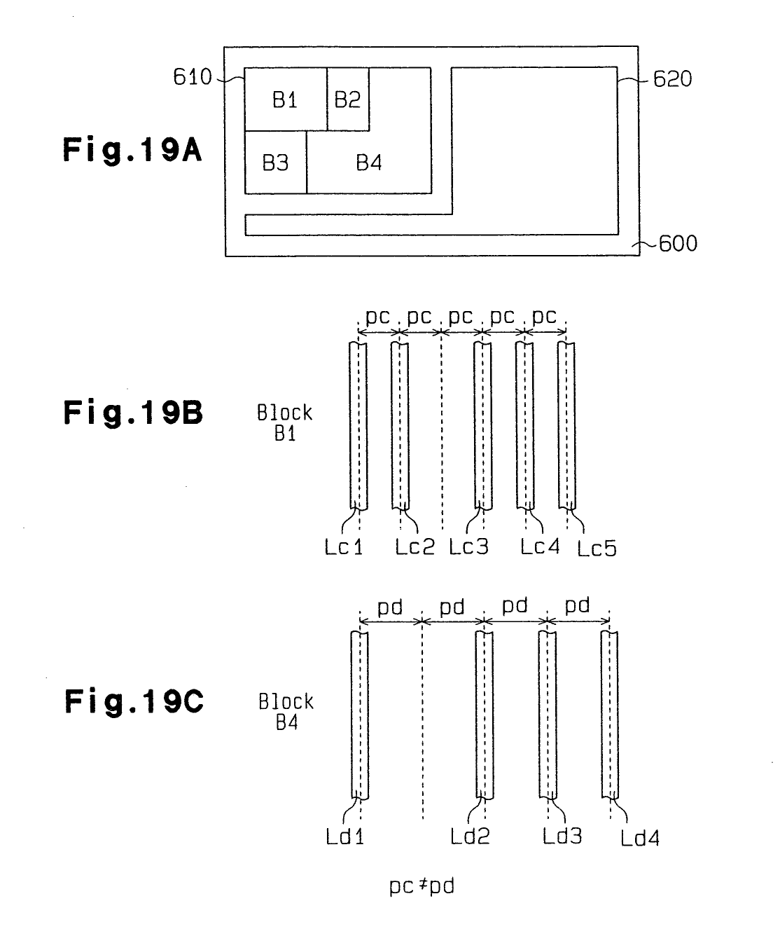

FIG. 19A is a top view of a semiconductor integrated circuit 600 having a logic circuit area 610 where a logic circuit is formed and a memory circuit area 620 where a memory, such as DRAM, is formed. The logic circuit area 610 comprises functional blocks B1 to B4. The logic circuit area 610 is the area that is fabricated based on the above-described design of each embodiment.

FIG. 19B shows wires of the functional block B1 of the logic circuit area 610. The functional block B1 has substantially parallel wires Lc1 to Lc5 and the pitches of the center axes of the wires Lc1 to Lc5 are an integer multiple of a predetermined minimum pitch pc. The pitch between the wires Lc1 and Lc2, the pitch between the wires Lc3 and Lc4 and the pitch between the wires Lc4 and Lc5 are the minimum pitch pc. The pitch between the wires Lc2 and Lc3 is twice the minimum pitch pc.

Fig. l9C shows wires of the functional block B4 of the logic circuit area 610. The functional block B4 has substantially parallel wires Ld1 to Ld4 and the pitches of the center axes of the wires Ld1 to Ld4 are an integer multiple of a predetermined minimum pitch pd. The pitch between the wires Ld2 and Ld3 and the pitch between the wires Ld3 and Ld4 are the minimum pitch pd. The pitch between the wires Ld1 and Ld2 is twice the minimum pitch pd.

The minimum pitch pc of the functional block B1 differs from the minimum pitch pd of the functional block B4. The minimum pitch pc and the minimum pitch pd can be set in such a way that one of the minimum pitches does not become an integer multiple of the other.

In the case where the wire pitch is set for each functional block, it is desirable to set the upper limit of the crosstalk noise lower for a functional block which demands faster operation. It is therefore desirable that the wire pitch should be made wider for such a functional block which demands a faster operation.

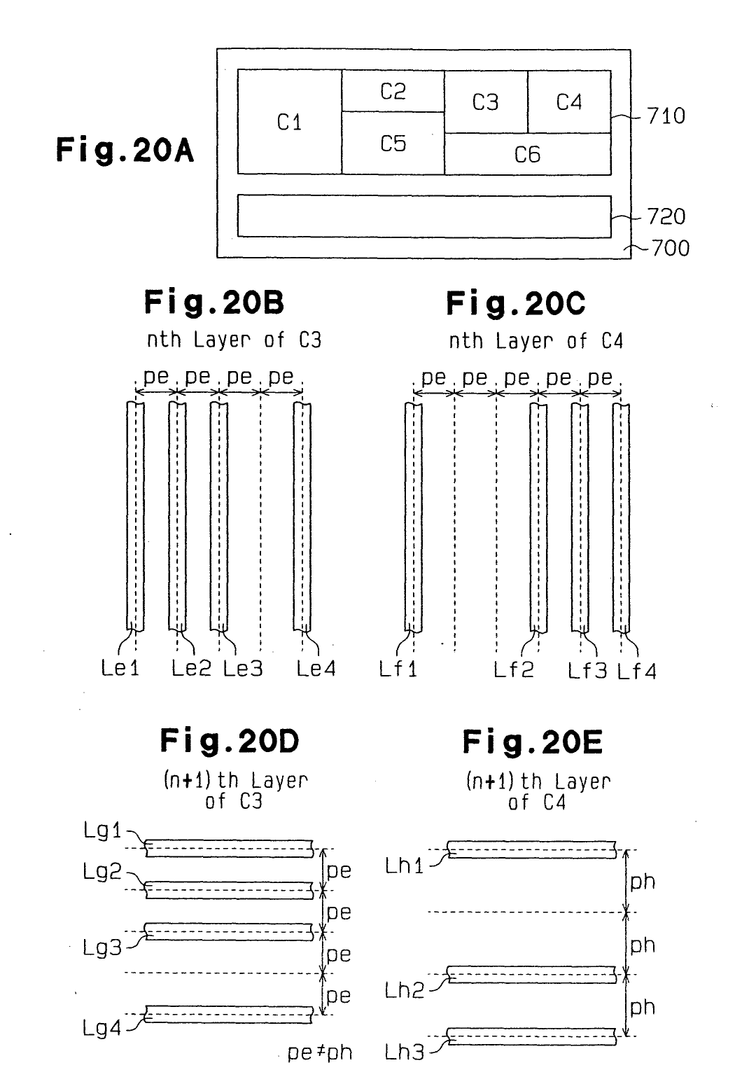

As shown in FIGS. 20A to 20E, the grid pitch may differ from one wiring layer to another and from one functional block to another.

As shown in FIG. 20A, a semiconductor integrated circuit 700 has a logic circuit area 710 where a logic circuit is formed and an interface area 720 where an input/output circuit (I/O) is formed. The logic circuit area 710 comprises functional blocks C1 to C6. The logic circuit area 710 is the area that is fabricated based on the above-described design of each embodiment.

FIGS. 20B and 20C respectively show the wires of the functional block C3 and functional block C4 in the n-th wiring layer. FIGS. 20D and 20E respectively show the wires of the functional block C3 and functional block C4 in the (n+1)th wiring layer.

As shown in FIG. 20B, the n-th wiring layer of the functional block C3 has substantially parallel wires Le1 to Le4. As shown in FIG. 20D, the (n+1)th wiring layer of the functional block C3 has substantially parallel wires Lg1 to Lg4. The pitches of the center axes of the wires Le1 to Le4 and Lg1 to Lg4 are an integer multiple of a predetermined minimum pitch pe. As shown in FIG. 20C, the n-th wiring layer of the functional block C4 has substantially parallel wires Lf1 to Lf4 the pitches of whose center axes are an integer multiple of the minimum pitch pe. As shown in FIG. 20E, the (n+1)th wiring layer of the functional block C4 has substantially parallel wires Lh1 to Lh3. The pitches of the center axes of the wires Lh1 to Lh3 are an integer multiple of a predetermined minimum pitch ph. The minimum pitch pe and the minimum pitch ph can be set in such a way that one of the minimum pitches does not become an integer multiple of the other.

An integer multiple of the auxiliary pitch kα may not coincide with the basic pitch α. In this case, the degree of freedom of wire connection is improved if the auxiliary pitch kα is smaller than the basic pitch α.

The grid may not define the position of the center axis of a wire.

In the first embodiment and its modifications, the automatic routing tool is not limited to the global routing section 22 and the detailed routing section 24. For example, the global routing section 22 in the first embodiment may be omitted. In the case where the automatic routing tool is an operational tool which performs wire connection by repeating try and error, for example, the initial stage of try and error is defined as trial routing process.

The automatic routing tool should not necessarily use a grid. Even in this case, it is effective to permit the wire pitch to be set in such a way that the pitch of the center axes of a plurality of wires becomes an integer multiple of a predetermined basic pitch and a pitch which is equal to or greater than the basic pitch and does not become an integer multiple of the basic pitch.

The design technique for a semiconductor integrated circuit may employ, for example, a gate array design different from the standard cell design.

The present examples and embodiment are to be considered as illustrative and not restrictive, and the invention is not to be limited to the details given herein, but may be modified within the scope and equivalence of the appended claims.

What is claimed is:

1. A semiconductor integrated circuit comprising:
a wiring layer having a region; and
a plurality of wires provided substantially in parallel to one another in the region of the wiring layer, each wire having a center axis extending in the longitudinal direction, a pitch of adjacent wires defined by distance between the center axes being an integer multiple of a predetermined minimum pitch and a value different from an integer multiple of a minimum design-rule dimension for a fabrication process for the semiconductor integrated circuit.

2. A semiconductor integrated circuit comprising:
a plurality of functional blocks each having a predetermined function and including functional cells; and
a plurality of wires arranged substantially in parallel to one another in each functional block for connecting the plurality of functional cells together, each wire having a center axis extending in the longitudinal direction, a pitch of the wires defined by distance between the center axes being an integer multiple of a minimum pitch, the minimum pitch in one selected functional block being different from that in another functional block.

3. The semiconductor integrated circuit according to claim 2, wherein the minimum pitch in the selected one functional block differs from an integer multiple of the minimum pitch in the another functional block.

4. A semiconductor integrated circuit comprising:
a plurality of wiring layers, with at least one wiring layer having a predetermined region;
functional blocks each having a predetermined function and including functional cells; and
a plurality of wires arranged substantially in parallel to one another in the predetermined region in the at least one of the wiring layers for connecting the functional cells together in each functional block, each wire having a center axis extending in the longitudinal direction, a pitch of the plurality of wires defined by distance between the center axes in each functional block being an integer multiple of a predetermined minimum pitch, the minimum pitch in one selected functional block being different from that in another functional block.

5. The semiconductor integrated circuit according to claim 4, wherein the minimum pitch in the selected one functional block differs from an integer multiple of the minimum pitch in the another functional block.

6. A semiconductor integrated circuit comprising:
a plurality of wiring layers, with at least one of the wiring layers having first and second regions;
a plurality of first wires arranged in parallel to one another in the first region in the at least one of the plurality of wiring layers, a pitch of the plurality of wires in the first region being an integer multiple of a predetermined first basic pitch; and
a plurality of second wires arranged in parallel to one another in the second region in the at least one wiring layer, a pitch of the second wires being an integer multiple of a predetermined second basic pitch, the predetermined first basic pitch being different from an integer multiple of the predetermined second basic pitch.

7. A design method for a semiconductor integrated circuit, the method comprising the steps of:
placing a plurality of functional cells; and
routing a plurality of wires for connecting the functional cells, each wire having a center axis extending in the longitudinal direction, wherein the step of routing wires includes setting pitches between the center axes of the plurality of wires to either a value of an integer multiple of a minimum design-rule dimension for a fabrication process of the semiconductor integrated circuit or a value equal to or greater than the minimum design-rule dimension and different from an integer multiple of the minimum design-rule dimension.

8. A design method for a semiconductor integrated circuit having a plurality of wiring layers, the method comprising the steps of:
setting a wire pitch for each of the plurality of wiring layers;
tentatively routing a plurality of wires at the wire pitch set for each layer of the plurality of wiring layers;
determining whether all of functional cells of the semiconductor integrated circuit have been connected by that tentative routing;
computing a peak value of crosstalk noise produced between the plurality of wires;
checking if the peak value of the crosstalk noise is equal to or less than a predetermined upper limit; and
repeating the step of tentatively routing, the step of determining and the step of computing while changing the wire pitch until all connections are completed and the peak value of the crosstalk noise is equal to or less than the predetermined upper limit.

9. The design method according to claim 8, wherein each wire has a center axis and the wire pitch is distance between center axes of wires in the plurality of wires and the step of setting the wire pitch includes setting the wire pitch to either a value of an integer multiple of a minimum design-rule dimension for a fabrication process of the semiconductor integrated circuit or a value equal to or greater than the minimum design-rule dimension and different from an integer multiple of the minimum design-rule dimension.

10. A design method for a semiconductor integrated circuit, comprising the steps of:
placing a plurality of functional cells;
setting a plurality of wire pitches;
tentatively routing a plurality of wires for connecting the plurality of functional cells in accordance with each of the plurality of wire pitches and tentatively connecting the plurality of functional cells, thereby generating a plurality of trial routing data;
analyzing a degree of wire congestion and crosstalk noise for each trial routing of the plurality of trial routing data;
predicting connection time needed for a final connection process for the plurality of functional cells for each trial routing of the plurality of trial routing data based on a result of the congestion analysis;
predicting crosstalk noise after final connection of the plurality of functional cells for each of the plurality of trial routing data based on a result of the crosstalk noise analysis; and
determining an optimal wire pitch from the plurality of wire pitches based on results of predicting the connection time and the crosstalk noise.

11. The design method according to claim 10, wherein the step of placing the plurality of functional cells is carried out using standard cells, and the design method further comprises the steps of:
determining based on a result of the analyzing the degree of wire congestion whether completion of detailed routing is possible between temporary layout of the plurality of wires and final decision of the wire pitches for each trial routing of the plurality of trial routing data; and
changing a ratio of an area of the functional cells to the total area of the semiconductor integrated circuit for trial routing data whose completion of detailed routing has been determined impossible, whereby after the ratio of the area is changed, the step of placing the plurality of functional cells, the step of setting the wire pitches, the step of tentatively routing the plurality of wires in accordance with the wire pitches, and tentatively connecting the plurality of functional cells to generate a plurality of trial routing data and the step of analyzing the degree of wire congestion are repeated.

12. A design method for a semiconductor integrated circuit including a plurality of functional cells, the method comprising the steps of:
tentatively connecting the plurality of functional cells by a plurality of wires in an arithmetic operation with a relatively small load, thereby generating trial routing data;
analyzing a degree of wire congestion and crosstalk noise for the trial routing data;
predicting connection time needed for a final connection process for the plurality of functional cells based on a result of the analyzing the degree of wire congestion;
predicting crosstalk noise after the final connection process of the plurality of functional cells based on a result of the analyzing crosstalk noise; and
evaluating whether the trial routing data is an optimal one or not based on results of predicting the connection time and the crosstalk noise.

13. The design method according to claim 12, wherein the step of evaluating includes weighting the result of predicting connection time and the result of analyzing crosstalk noise and making an evaluation in accordance with one of a sum and a product of weighted connection time and weighted crosstalk noise.

14. A design method for a semiconductor integrated circuit having a plurality of wiring layers, the method comprising the steps of:
setting a wire pitch for each layer of the plurality of wiring layers;
tentatively routing a plurality of wires at the wire pitch to thereby generate trial routing data;
checking a degree of wire congestion of the trial routing data;
checking power consumption of the trial routing data; and
determining an optimal wire pitch from the degree of wire congestion and the power consumption of the trial routing data.

15. The design method according to claim 14, wherein each wire has a center axis and the wire pitch is distance between center axes of wires in the plurality of wires and the step of setting the wire pitch includes setting the wire pitch to either a value of an integer multiple of a minimum design-rule dimension for a fabrication process of the semiconductor integrated circuit or a value equal to or greater than the minimum design-rule dimension and different from an integer multiple of the minimum design-rule dimension.

16. A design method for a semiconductor integrated circuit including a plurality of functional cells, the method comprising the steps of:
setting a wire pitch;
tentatively routing a plurality of wires in accordance with the set wire pitch to tentatively connect the plurality of functional cells to generate trial routing data including information for the plurality of wires tentatively routed and the plurality of functional cells;
analyzing a degree of wire congestion and power consumption of the trial routing data; and
evaluating whether the trial routing data is an optimal one or not, based on the degree of wire congestion and the power consumption of the trial routing data.

17. The design method according to claim 16, wherein each wire has a center axis and the wire pitch is distance between center axes of wires in the plurality of wires and the step of setting the wire pitch includes setting the wire pitch to either a value of an integer multiple of a minimum design-rule dimension for a fabrication process of the semiconductor integrated circuit or a value equal to or greater than the minimum design-rule dimension and different from an integer multiple of the minimum design-rule dimension.

18. The design method according to claim 16, wherein the step of setting the wire pitch includes simultaneously setting a plurality of values, the step of tentatively routing includes tentatively routing the plurality of wires in accordance with each of a plurality of wire pitches and generating a plurality of trial routing data each having a plurality of wire pitches, and wherein the step of evaluating includes selecting an optimal routing data from the plurality of trial routing data.

19. A design method for a semiconductor integrated circuit having a plurality of wiring layers, the method comprising the steps of:
placing a plurality of functional cells in each of the wiring layers in accordance with a predetermined cell-utilization-ratio;
setting a plurality of wire pitches for each of the plurality of wiring layers;
generating trial routing data by tentatively routing a plurality of wires for connecting the plurality of functional cells at the set wire pitch;
checking a degree of wire congestion of the trial routing data;
when the wire congestion is unacceptable, repeating the steps of placing a plurality of functional cells, generating trial routing data and checking the degree of wire congestion in accordance with a smaller cell-utilization-ratio or in accordance with a smaller wire pitch for at least one wiring layer selected from the plurality of wiring layers;
when the wire congestion is acceptable, checking the crosstalk noise of the trial routing data;
selecting a trial routing whose wire congestion and crosstalk noise are both optimal; and
determining a final layout of the plurality of wires in accordance with that wire pitch that is used for the selected routing.

20. The design method according to claim 19, further comprising the step of selecting an upper wiring layer in the plurality of wiring layers by priority as the at least one wiring layer.
